(19) United States
(12) Patent Application Publication
(10) Pub. No.: US 2005/0092597 A1
(43) Pub. Date: May 5, 2005

(54) Method of forming thin-film electrodes

(76) Inventors: James O'Neil, Corvallis, OR (US); Peter Mardilovich, Corvallis, OR (US); Gregory Herman, Albany, OR (US); David Champion, Lebanon, OR (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/697,618

(22) Filed: Oct. 29, 2003

(51) Int. Cl. B05D 5/12; C23C 14/32

(52) U.S. Cl. 204/192.15; 427/115; 204/192.12; 204/298.23

(57) ABSTRACT

A method of forming a fuel cell electrode includes providing a substrate and at least one deposition device, developing a deposition characteristic profile having at least one porous layer based on pre-determined desired electrode properties, forming a film in accordance with the deposition characteristic profile by sputtering material from the deposition device while varying a relative position of the substrate in relation to the deposition device with respect to at least a first axis.

### BACKGROUND

During the past several years, the popularity and viability of fuel cells for producing both large and small amounts of electricity has increased significantly. Fuel cells conduct an electrochemical reaction with reactants such as hydrogen and oxygen to produce electricity and heat. Fuel cells are similar to batteries except they can be “recharged” while providing power. In addition, fuel cells are cleaner than other sources of power, such as devices that combust hydrocarbons.

Fuel cells provide a DC (direct current) voltage that may be used to power motors, lights, computers, or any number of electrical appliances. A typical fuel cell includes an electrolyte disposed between an anode and a cathode. There are several different types of fuel cells, each using a different chemistry. Fuel cells are usually classified by the type of electrolyte used. Fuel cells are generally categorized into one of five groups: proton exchange membrane (PEM) fuel cells, alkaline fuel cells (AFC), phosphoric-acid fuel cells (PAFC), solid oxide fuel cells (SOFC), and molten carbonate fuel cells (MCFC).

Most SOFCs include an electrolyte made of a solid-state material such as a fast oxygen ion conducting ceramic. In order to provide adequate ionic conductivity in the electrolyte, SOFCs typically operate in the 500 to 1000 C temperature range. On each side of the electrolyte is an electrode; an anode on one side and a cathode on the other. An oxidant such as air is fed to the cathode that supplies oxygen ions to the electrolyte. A fuel such as hydrogen or methane is fed to the anode where it reacts with oxygen ions transported through the electrolyte. This reaction produces electrons, which are then delivered to an external circuit as useful power.

Throughout the operation of an SOFC, a cell is often cycled between room temperature and its full operating temperature. This thermal cycling causes the housing materials to contract and expand according to their coefficients of thermal expansion. This expansion and contraction introduces thermal stresses that may be transferred through the seals and other structural components directly to the ceramic cell. These thermal stresses effectively reduce the service life of an SOFC by compromising the seals or breaking the structurally brittle ceramic cells. Furthermore, expansion of the anode and cathode through redox cycling is a mechanism for considerable stress. In the case of the anode the metallic portion of the cermet will become oxidized when the fuel supply is shut down. The resulting oxidation causes an expansion of the anode, which can lead to cell failure. A similar effect can also be observed to occur for the cathode. Some systems attempt to address this through sophisticated start-up and shut-down procedures that expend additional fuel, adopt continuous-operation practices, or attempt to identify very well thermally matched materials that are resilient to thermal cycling at the expense of device performance (due to poor catalytic performance of chosen materials).

### SUMMARY

A method of forming a fuel cell electrode includes providing a substrate and at least one deposition device, developing a deposition characteristic profile having at least one porous layer based on pre-determined desired electrode properties, forming a film in accordance with the deposition characteristic profile by sputtering material from the deposition device while varying a relative position of the substrate in relation to the deposition device with respect to at least a first axis.

### BRIEF DESCRIPTION OF THE DRAWINGS

The accompanying drawings illustrate various embodiments of the present apparatus and method and are a part of the specification. The illustrated embodiments are merely examples of the present apparatus and method and do not limit the scope of the disclosure.

FIG. 1 is an electrode formation system according to one exemplary embodiment.

FIG. 2 is an electrode formation system according to one exemplary embodiment.

FIG. 3 is a flowchart illustrating a method of forming a thin-film electrode according to one exemplary embodiment.

FIG. 4A is a deposition thickness profile of a thin-film electrode according to one exemplary embodiment.

FIG. 4B is a concentration profile of a thin-film electrode according to one exemplary embodiment.

FIG. 5A is a deposition thickness profile of a thin-film electrode according to one exemplary embodiment.

FIG. 5B is a concentration profile of a thin-film electrode according to one exemplary embodiment.

FIG. 6A is a deposition thickness profile of a thin-film electrode according to one exemplary embodiment.

FIG. 6B is a concentration profile of a thin-film electrode according to one exemplary embodiment.

FIG. 7 is an electrode formation system according to one exemplary embodiment.

FIG. 7A is a deposition thickness profile of a thin-film electrode according to one exemplary embodiment.

FIG. 7B is a concentration profile of a thin-film electrode according to one exemplary embodiment.

FIG. 8 illustrates a thin-film electrode according to one exemplary embodiment.

FIG. 9 illustrates a fuel cell according to one exemplary embodiment.

FIG. 10 illustrates an electrode formation system according to one exemplary embodiment.

Throughout the drawings, identical reference numbers designate similar, but not necessarily identical, elements.

### DETAILED DESCRIPTION

A method of forming a fuel cell electrode includes providing a substrate and at least one deposition device, developing a deposition characteristic profile having at least one porous layer based on pre-determined desired electrode properties, forming a film in accordance with the deposition characteristic profile by sputtering material from the deposition device while varying a relative position of the substrate in relation to the deposition device with respect to at least a first axis.

As used herein and in the appended claims, a thin-film shall be broadly understood to mean a film having a thickness of less than 10 micrometers. Further, a porous layer shall be broadly understood to mean a layer having a porosity of about 25% or greater and a dense layer shall be broadly understood to mean a layer having a porosity of less than about 25%.

In the following description, for purposes of explanation, numerous specific details are set forth in order to provide a thorough understanding of the present method and apparatus. It will be apparent, however, to one skilled in the art that the present method and apparatus may be practiced without these specific details. Reference in the specification to “one embodiment” or “an embodiment” means that a particular feature, structure, or characteristic described in connection with the embodiment is included in at least one embodiment. The appearance of the phrase “in one embodiment” in various places in the specification are not necessarily all referring to the same embodiment.

Exemplary Structure

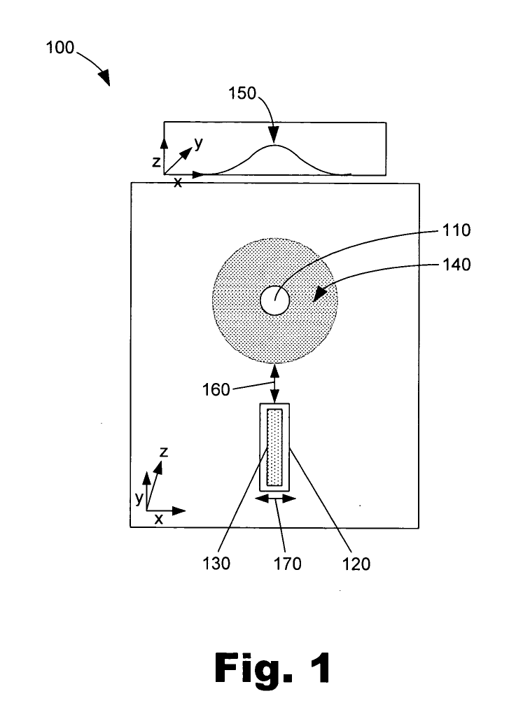

FIG. 1 illustrates a schematic view of an electrode forming system (100) that generally includes a deposition device such as sputter gun (110) and a substrate advancement mechanism (120) that moves a substrate (130) with respect to the sputter gun (110).

The material is deposited below the sputter gun (110) and the area on which material is deposited may form sputter pattern (140) corresponding to a thickness deposition profile (150). The density of the material deposited varies with the distance from the sputter gun (110) in the x-direction and/or y-direction. Accordingly, the sputter gun (110), which may be oriented in a substantially vertical alignment with respect to the substrate (130), deposits material in a manner that can be characterized by the thickness deposition profile (150). The thickness deposition profile (150) has a maximum value directly below the sputter gun (110) when in a substantially vertical alignment that decreases as the distance from the sputter gun (110) increases.

The advancement mechanism (120) is configured to advance the substrate (130) past the sputter gun (110) in a primary direction of travel (160). The advancement mechanism (120) is also capable of moving the substrate (130) in other directions such as in a second direction (170), such that the substrate (130) may be passed under the sputter gun (110) at different x-direction distances. In addition, the substrate (130) may be moved in the second direction (170) as it passes under the sputter gun (110). As a result, layers of differing densities may be formed on the substrate (130) by controlling or modulating the x-direction distance from the sputter gun (110) to the substrate (130) on successive passes under the sputter gun (110). The length of the successive passes of the substrate (130) in the primary direction of travel (160) under the sputter gun (110) will also determine the degree of morphological variance. The possibility also exists where the substrate-sputter gun distance z can be varied by either moving the substrate (130) or sputter gun (110). The formation of layers of gradient composition and/or morphological characteristics may also be accomplished by using multiple sputter guns.

Exemplary Implementation and Operation

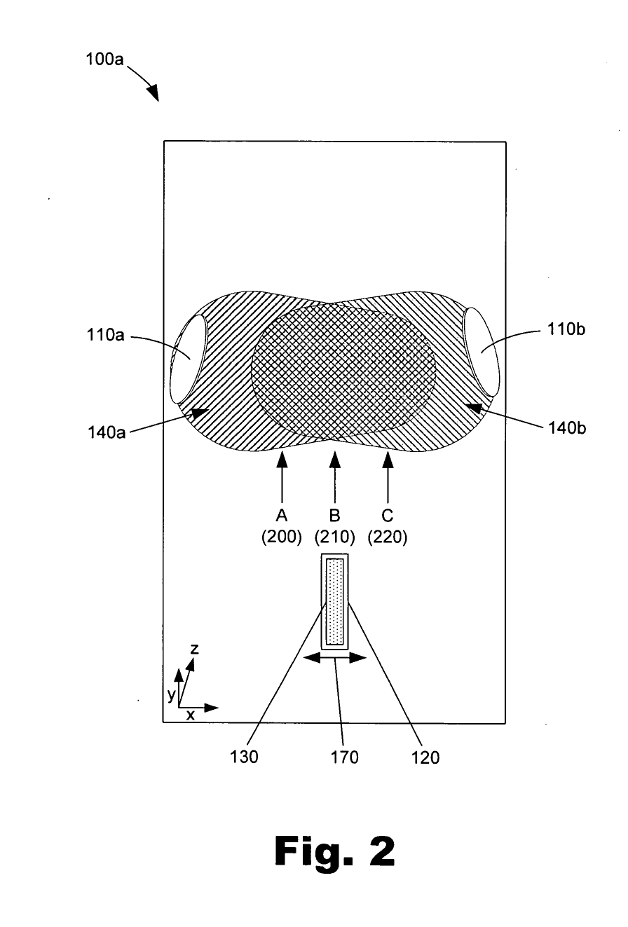

FIG. 2 illustrates an electrode forming system (100a) that includes a plurality of sputter guns (110a, 100b) that are opposingly positioned above a substrate (130) that rests on a substrate advancement mechanism (120). Similar to the sputter guns (110a, 110b) of FIG. 1, each of the sputter guns (110a, 110b) form sputter patterns (140a, 140b) of Target 1 and Target 2 materials respectively. The sputter patterns (140a, 140b) may overlap. Further, the size of the sputter patterns (140a, 140b) may be controlled independently, thereby forming different deposition profiles. Such a configuration allows for the formation of precisely controlled layers with compositional and/or morphological gradients. In addition, FIG. 2 illustrates advancement lines A, B, C (200, 210, 220). Formation of these layers and the significance of the advancement paths (200, 210, 220) will be discussed in more detail below.

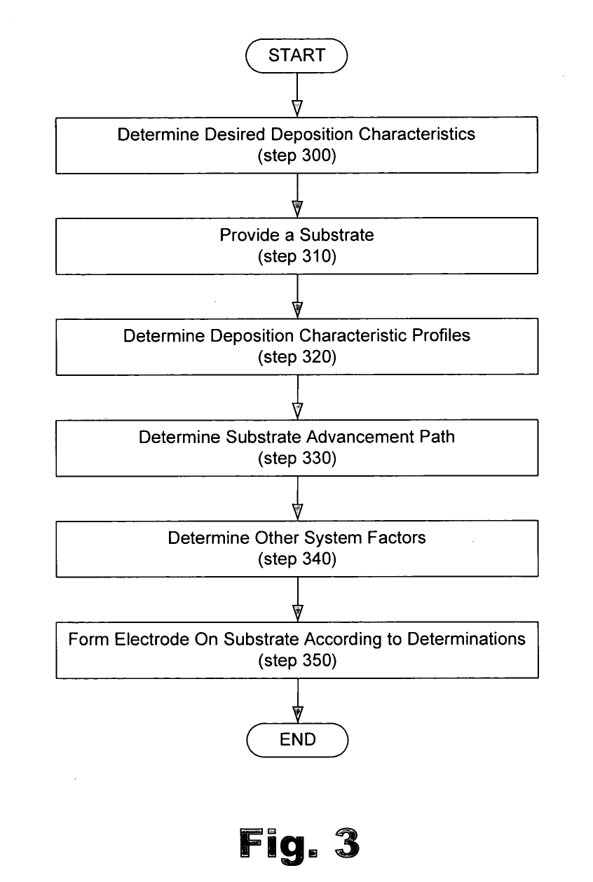

FIG. 3 is a flowchart of a method of forming a thin-film electrode having gradient properties. The first step of the process is to determine the desired deposition characteristics including the compositional and/or morphological characteristics of the electrode (300) that form compositional and/or morphological characteristic profiles in the film. Accordingly, this step includes a determination of the desired profiles of the deposition characteristics and their profiles. The next step in the process is to provide a substrate on which the electrode is to be formed (step 310). The substrate may be any suitable substrate. Examples may include porous ceramic substrates or dense electrolyte material.

Formation of the film on the substrate involves a determination of the necessary thickness deposition profiles of each of the sputter guns (step 320). The present process may utilize a system that includes at least one material deposition device such as a sputter gun. When sputtering material, each sputter gun creates a sputter deposition thickness profile similar to those shown in FIGS. 1, 4A, 5A, and 6A.

This step also involves a determination of how the necessary thickness deposition profiles created by at least one material deposition device or sputter gun may vary with respect to time. For example, in order to form a film with the desired characteristics determined above (step 300) it may be necessary to vary the thickness deposition profiles with respect to each other such that one is larger than the other during the entire formation process or during certain time periods of the formation process. In the case where a first thickness deposition profile is larger than the other, a substrate advancing between the sputter guns may experience Target 1 material from the first sputter gun before experiencing Target 2 material from the second sputter gun. This may allow for the control of compositional gradients within the film. This compositional control is due to less material being deposited at increased relative distances from the sputter guns. By using the first deposition thickness profile, the material from the first sputter gun will be applied at a relatively large distance. The material deposited at this distance will form a less dense layer, which may include pores, such as nano-pores, meso-pores and/or micro-pores. Nano-pores are pores of less than about 10 nm, mesopores are typically between about 10-100 nm in size, and micropores are greater than about 0.1 μm in size. For convenience, the formation of these pores will be collectively referred to as pores in the specification. The formation of these pores results in nano-chambers formed in the resulting layer, which are pore-sized chambers. These nano-chambers limit the size of metal nano particles through agglomeration (which improves their respective catalytic activity via higher surface area and/or quantum confinement affects), affect mass transport of reactants and products. Further, reduced pore size increases surface area, which increases the number of catalytic reaction sites. In addition, strain related to the curvature of the material to form the pores may affect the catalytic properties of the materials, etc.

Depending on the distance (primarily in the x-direction) of the substrate from the sputter guns, porous material deposited by the first sputter gun may be deposited on the substrate. In this situation, the relative morphology of the resulting film may include a larger percentage of porosity. As a result, control of the deposition thickness profiles allows the formation of films with compositional and/or morphological gradients.

The deposition thickness profiles may be controlled by varying the angle of the sputter gun with respect to each other and/or to the substrate, the amount of material deposited per unit time, or by any other suitable means. The deposition thickness profiles do not necessarily need to be varied. Formation of the compositional and/or morphological gradients may be controlled by any combination of varying the deposition thickness profiles and/or controlling the substrate advancement path and/or any other number of factors.

Consequently, the next step in the present process is to determine the substrate advancement path (step 330). The substrate advancement path refers to the path the substrate travels during formation of the thin film electrode. Control of the substrate advancement path may include variation of the advancement speed in any direction and/or control of the advancement of the substrate in any direction. Any substrate advancement path may be followed, including complex passes involving passes of varying duration or incomplete passes through the deposition zone. As discussed above, control of the location of the substrate may allow for the formation of morphological and/or compositional gradients. Multiple gradients may be formed during multiple passes under the sputter gun, or by passing the substrate back and forth under the sputter gun multiple times.

Control of the formation of the compositional and/or morphological gradients may also be controlled by factors other than modulation of the substrate advancement path and/or the deposition thickness profiles. For example, the thickness deposited by one sputter gun can be controlled independently of the other by varying power, substrate bias, sputter gun-to-substrate distance and magnetic field. System pressure can also change the deposition profiles, but not independently. Accordingly, other system factors must be determined (step 340)

Once all the variables of the process have been determined according to the preceding steps, the electrodes are formed on the substrate (step 350). The electrode is sputtered onto the substrate according to the variables discussed above in order to form the film with the pre-determined desired compositional and/or morphological characteristics.

As described, the present method provides a way for thin film electrodes to be made with precise control of compositional and morphological gradients through the film thickness. Such films have superior volumetric energy (energy per 1 μm of thickness) as anode and cathode of SOFC. Stability of anode (cermet) to red-ox cycling is also improved due to the presence of “nano-chambers” connected by less porous material (in z-direction). As a result, thin-film SOFC performance may be up to 850 mW/cm² or higher. In addition, the thin-film architecture by definition requires less material than other solutions.

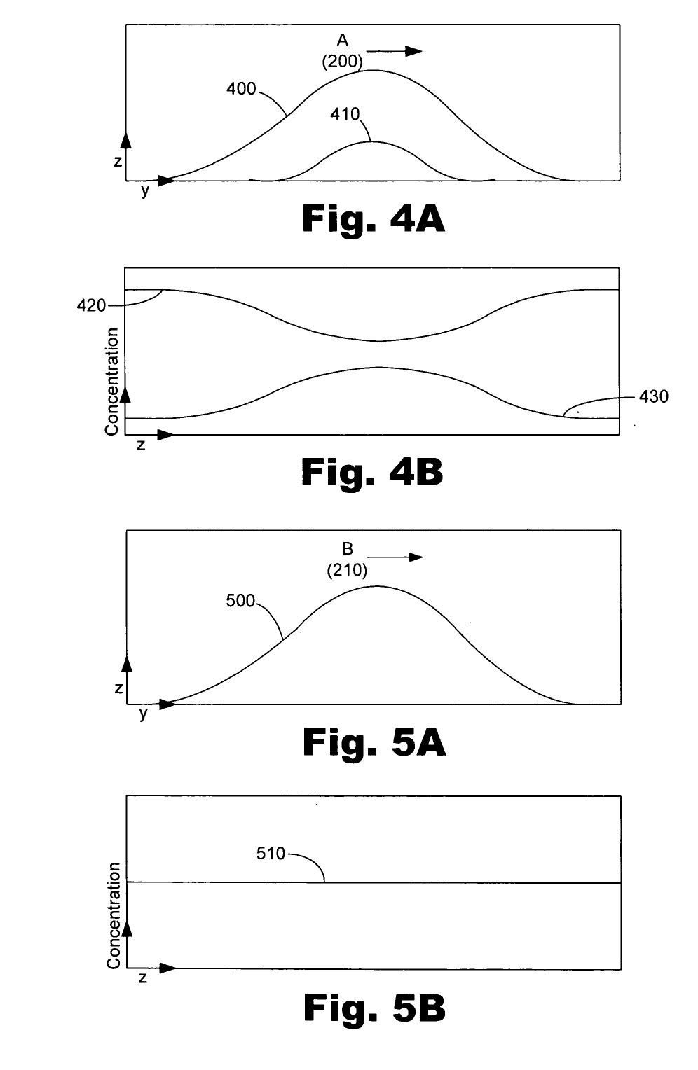

FIG. 4A illustrates the first and second deposition thickness profiles (400, 410) of Target 1 and 2 material deposited by the first and second sputter guns (110a,b; FIG. 2) with respect to the advancement direction A (200) and FIG. 4B illustrates the corresponding first and second concentration profiles (420, 430) of the same material with respect to the thickness direction. FIG. 4A illustrates thickness deposition profile (400, 410) of the substrate (130; FIG. 2) as it advances in the y-direction past the sputter guns (110a, b; FIG. 2) along the advancement line A (200; FIG. 2). As shown in FIG. 4A, if the substrate travels along advancement line A (200), it will have a higher concentration of Target 1 material from the first sputter gun (110a) than from the second sputter gun (110b). As seen in FIG. 4B, there will also be composition gradients (420, 430) through the film. Traveling along line A (200), the substrate will initially be deposited with just Target 1 material, with the percentage of Target 2 material increasing as the substrate moves to the right. After passing underneath the sputter guns (110a, b), the percentage of Target 2 material will decrease until only Target 1 material is being deposited. The result is the compositional gradients shown in FIG. 4B. The compositional profiles (420, 430) are shown with respect to the z-direction, in which the abscissa represents the thickness direction and the ordinate represents the relative concentration.

FIG. 5A illustrates the first and second deposition thickness profiles (500) with respect to the advancement direction B (210) and FIG. 5B illustrates the concentration profile (510) with respect to the thickness direction. According to the exemplary deposition profiles of FIG. 2, the deposited film will not have a composition or thickness gradient if deposited along Line B (210), but instead will consist of two identical deposition thickness profiles (500) and composition profiles (510). Again, the concentration profiles (510) are shown with respect to a substrate (130; FIG. 2) passing to the right along direction B (210) and the compositional profiles (510) are shown with respect to the z-direction, in which the abscissa represents the thickness direction and the ordinate represents the relative concentration.

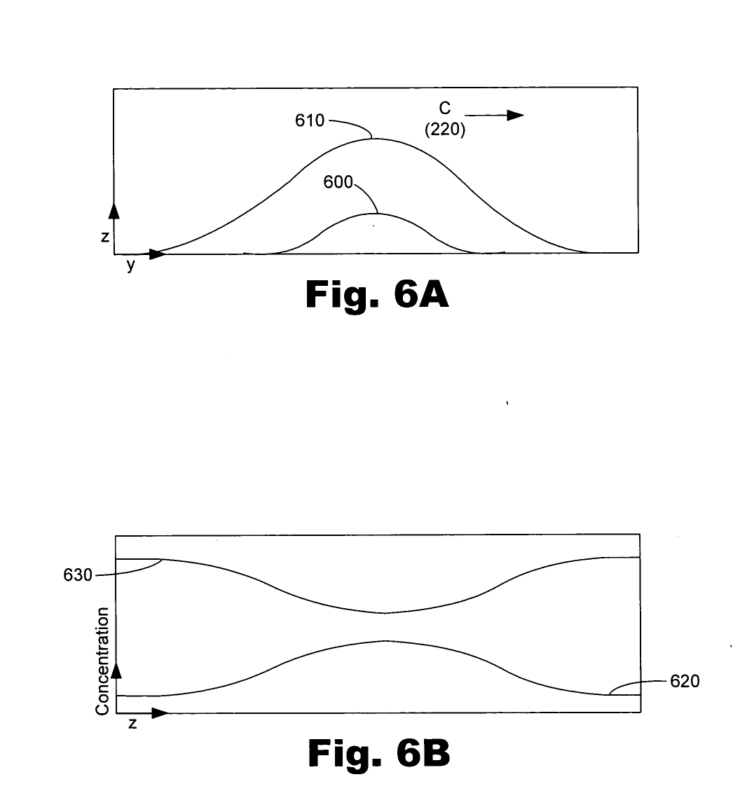

FIG. 6A illustrates the resulting first and second deposition thickness profiles (600, 610) with respect to the advancement direction C (220) and FIG. 6B illustrates the concentration profiles (620, 630) with respect to the thickness direction. A film with the opposite concentration profiles (620, 630) and thickness deposition profiles (600, 610) of the profiles in FIG. 4A and FIG. 4B will be deposited if the substrate (130; FIG. 2) travels along line C (220), rather than line A (200). As above, the deposition thickness profiles (600, 610) are shown with respect to a substrate (130; FIG. 2) passing to the right and the compositional profiles (620, 630) are shown with respect to the z-direction, in which the abscissa represents the thickness direction and the ordinate represents the relative concentration.

As a result, the present process provides desired and unique thin-film architecture. Film composition and porosity/density are adjusted with a periodicity through the bulk film. Modulation of the porosity enables improved mechanical performance of the films. Adjusting the film composition in concert with film porosity modulation improves catalytic reaction rate and mobility of the active species because surface mobility rates are significantly higher than bulk mobility rates.

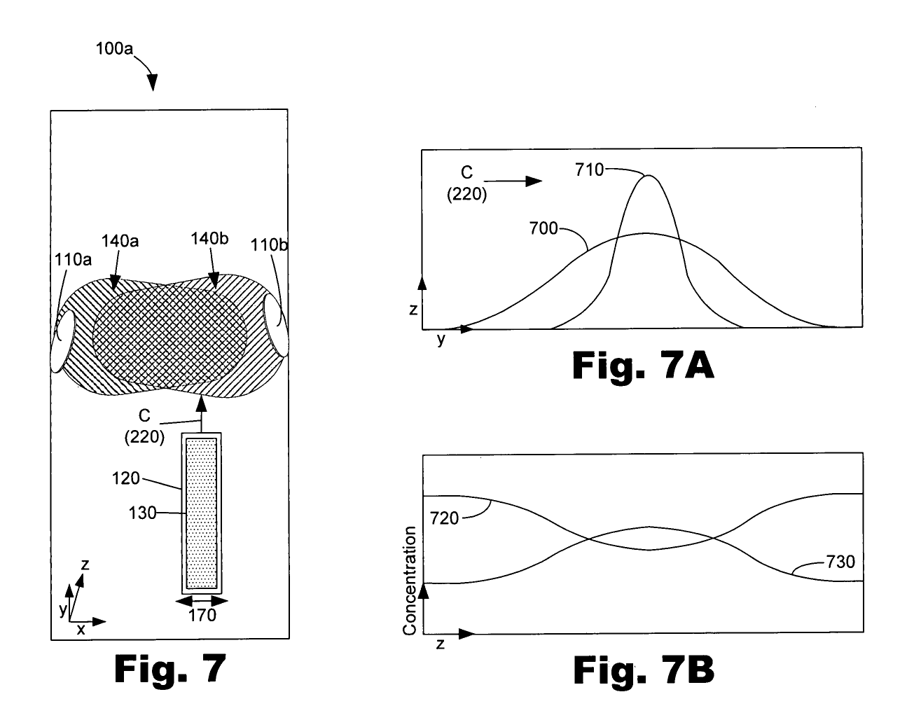

FIG. 7 illustrates a situation wherein the substrate (130) travels along substrate advancement path C (220) in a similar fashion to the implementation shown in FIG. 6A-B. In the present implementation, other factors are controlled, such as the bias of the substrate (130) such that although the substrate (130) experiences Target 1 material first, an equal amount of Target 2 material is deposited in a shorter period resulting in the higher peak of the second deposition thickness profile (710). The first and second thickness deposition profiles (700, 710) are illustrated in FIG. 7A, while the resulting concentration profiles (720, 730) are illustrated in FIG. 7B. Accordingly, modulation of the thickness deposition profiles (700, 710) and the substrate advancement path (220) provides for the control of the formation of a variety of films having compositional and morphological gradients. In addition to modulating the location of a substrate advancement path (220), formation of compositional and/or morphological gradients may also be controlled by modulating the substrate advancement speed.

As previously described, the substrate advancement mechanism (120) is capable of controlling the relative motion of the substrate with respect to the sputter guns (110a, b). This control may involve longer or more complete passes through the sputter zones and passes through the sputter zone that involve variation of movement of the substrate (130) in several directions during multiple passes. Longer or shorter passes, as well as multiple direction passes further facilitate the simultaneous modulation or control of compositional characteristics and morphological characteristics such as porosity. Accordingly, the present method and system provide for the formation a unique thin-film structure that is remarkably resilient to thermal device cycling. In addition, operating efficiencies of SOFC devices that have suffered from inefficient anode/cathode film designs are improved due to the unique film architecture that incorporates graded films in the thickness-direction as well as graded or alternating porosity. Films constructed in this manner may deliver significant improvements over prior art. Additionally this process is well controlled and volume production capable.

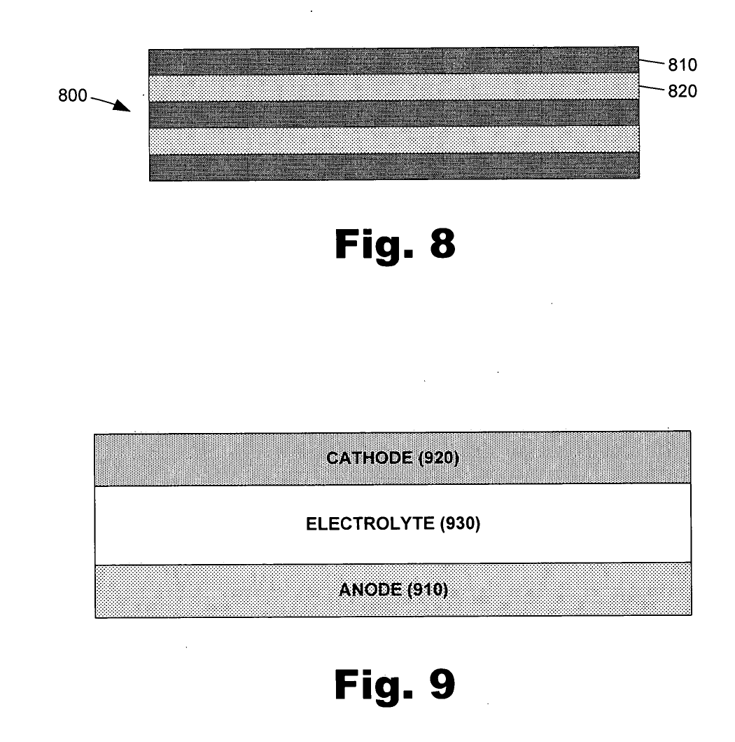

FIG. 8 illustrates a thin-film electrode (800) formed according to the present method. The electrode (800) includes alternating dense layers (810) and less dense layers (820). The less dense layers include nano-pores. Nanopores significantly increase the surface area of catalytic systems. Although the specific catalytic activity for a given material is approximately constant, the overall catalytic activity increases with increased surface area. Nanopores also help increase fuel and O₂ utilization by limiting diffusion of unreacted species away from the catalytic surface. This is especially true with multilayer systems of alternating dense and porous layers. These systems create multiple “bottlenecks” for the reactant species, causing the reactants to remain in small “reaction chambers” (porous layers) thereby increasing the probability of reaction. Specific to the anode cermet systems, nano-pores, compared to larger pores, decrease film stress during redox cycling and improve performance. A ceramic frame of nanopores suppresses agglomeration of the metal component, which results in smaller pieces of metal. Smaller pieces of metal expand/contract less during redox cycling and have a higher surface area, which results in higher catalytic activity. The thin-film electrode may include any multiples of compositional and/or morphological gradients. The thin-film electrodes may be formed by the present method and system, which include anodes, cathodes, and/or electrolytes. Suitable anode materials may include nickel, platinum, Ni-Yttria Stabilized Zirconia (YSZ), Cu—YSZ, Ni-Samarium Doped Ceria (SDC), Ni-Gadolinium Doped Ceria (GDC), Cu—SDC, Cu-GDC. Suitable cathode materials may include silver, platinum, samarium strontium cobalt oxide (SSCO, SmₓSr_{y}CoO_{3-δ}), barium lanthanum cobalt oxide (BLCO, BaₓLa_{y}CoO_{3-δ}), gadolinium strontium cobalt oxide (GSCO, GdₓSr_{y}CoO_{3-δ}), lanthanum strontium manganite (LSM, LaₓSr_{y}MnO_{3-δ}) and lanthanum strontium cobalt ferrite (La_{w}SrₓCo_{y}Fe_{z}O_{3-δ}) and mixtures thereof.

FIG. 9 illustrates a fuel cell (900) having an anode (910), a cathode (920), and an electrolyte (930) formed according to the present method and system. The layers comprising the electrodes are thin, and may be between about 10-500 nanometers in thickness. Further, these layers may between 30-80 nanometers in thickness. Varying the pore size, porosity, layer thicknesses, and overall film thickness of the electrodes (910, 920) may significantly improve the performance of the fuel cell (900). SSCO is known to be a higher performing cathode material than LSM, due to SSCO's higher oxygen reduction activity, ionic and electronic conductivity, and reduced polarization losses at the interfaces. Despite these possible advantages, SSCO is often avoided due to its very high coefficient of thermal expansion (TCE). An electrode formed according to the present method, having layered films of different porosity in a thin-film structure; facilitate the use of higher performing electrodes by overcoming significant TCE mismatch. The electrodes (910, 920) are an order of magnitude thinner than typical electrodes; the electrodes (910, 920) also have a significantly higher volumetric power density. In addition, the electrodes (910, 920) reduce the mass transport limitations that can reduce performance at high power operation. Variation of composition in the electrodes also has other benefits related to controlling the catalytic particle size, catalytic activity and selectivity, and ion and electron conduction. Controlling these factors through the methods described in this application gives the ability to maximize performance.

### ALTERNATIVE EMBODIMENTS

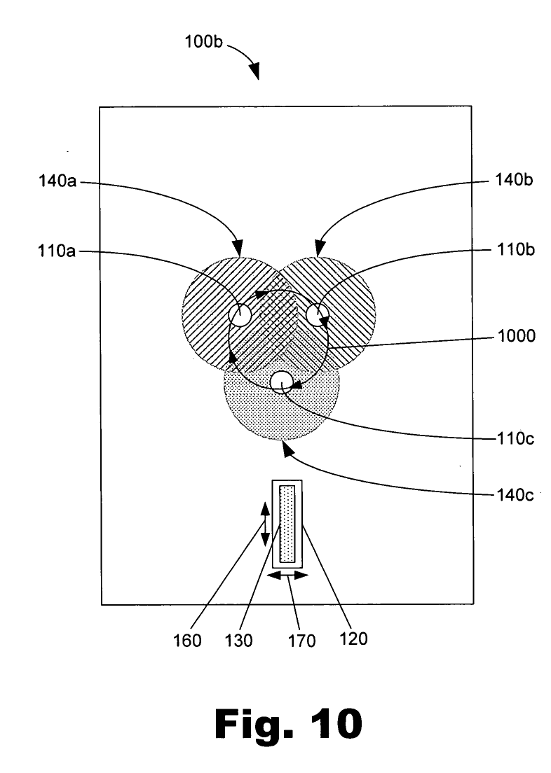

An alternative implementation, shown in FIG. 10, illustrates an electrode formation system (100b) that generally includes three deposition devices (110, b, c). In a similar manner to the systems described above (100; FIG. 1, 100a; FIG. 2), a film of precisely controlled composition and/or morphological characteristics may be formed by modulating or controlling any number of substrate advancement paths, thickness deposition profiles, the speed of advancement, and/or other factors such as varying power, substrate bias, sputter gun-to-substrate distance, magnetic field, or using a shutter to selectively block at least a portion of a material expelled from at least one of the deposition devices (110a, b, c). An example an advancement path (1000) is shown. Any number of advancement paths may be followed to achieve any number of compositional and/or morphological gradients in the resulting film. The advancement path and/or the factors may be controlled independently or combined, depending on the desired characteristics.

The present configuration provides superior fuel cell performance in the form of improved cell cycling capability and an estimated 2× power density. Due to the thin film nature of this architecture and the alternating porosity the system is significantly more robust to thermal and oxidation cycling. While the above illustrated implementations illustrate one, two, and three sputter gun systems, any number of deposition devices may be utilized. In addition, control of any number of variables may be employed to form an electrode with thin film architecture having the desired characteristics.

The preceding description has been presented only to illustrate and describe the present method and apparatus. It is not intended to be exhaustive or to limit the disclosure to any precise form disclosed. Many modifications and variations are possible in light of the above teaching. It is intended that the scope of the invention be defined by the following claims.

1. A method of forming a thin-film fuel cell electrode, comprising:
providing a substrate and at least one deposition device;
developing a deposition characteristic profile having at least one porous layer based on pre-determined desired electrode properties; and
forming a film in accordance with said deposition characteristic profile by depositing material from said deposition device while varying a relative position of said substrate in relation to said deposition device with respect to at least a first axis.

2. The method of claim 1, wherein forming said film further comprises varying a power supplied to said deposition device.

3. The method of claim 1, wherein forming said film further comprises varying a bias of said substrate to a deposited material.

5. The method of claim 1, wherein forming said film further comprises varying an applied magnetic field.

6. The method of claim 1, wherein varying said relative position comprises advancing said substrate along a substrate advancement path.

7. The method of claim 1, wherein varying said relative position comprises varying a speed with which said substrate passes said deposition device.

8. The method of claim 1, wherein varying said relative position comprises varying a distance at which said substrate passes said deposition device.

9. The method of claim 8, wherein varying said relative position further comprises varying a speed with which said substrate passes said deposition device.

10. The method of claim 1, wherein varying said relative position comprises traversing said substrate back and forth past said deposition device.

11. The method of claim 10, wherein varying said relative position further comprises varying a distance in multiple directions.

12. The method of claim 11, wherein varying said relative position further comprises varying a speed with which said substrate passes said deposition device.

13. The method of claim 12, wherein said deposition characteristic profile comprises at least composition gradient profile and at least one morphological gradient profile.

14. The method of claim 13, wherein said morphological profile comprises alternating dense film layers and porous film layers having nano-chambers.

15. The method of claim 14, wherein said deposition device comprises a sputter gun.

16. The method of claim 1, further comprising providing a second deposition device and depositing a second material from said second device onto said substrate while varying the relative position of said substrate in relation to said second deposition device with respect to at least a first axis.

17. The method of claim 16, wherein forming said film further comprises varying a power supplied to said deposition device.

18. The method of claim 16, wherein forming said film further comprises varying a bias of said substrate to a deposited material.

19. The method of claim 16, further comprising varying a distance between said deposition devices.

20. The method of claim 16, wherein forming said film further comprises varying an applied magnetic field.

21. The method of claim 16, wherein varying said relative position comprises advancing said substrate along a substrate advancement path.

22. The method of claim 16, wherein varying said relative position comprises varying a speed with which said substrate passes said deposition device.

23. The method of claim 16, wherein varying said relative position comprises varying a distance between said deposition devices.

24. The method of claim 23, wherein varying said relative position further comprises introducing the use of shutter to selectively block at least a portion of a material expelled from at least one of said deposition devices.

25. The method of claim 16, wherein varying said relative position comprises traversing said substrate back and forth past said deposition device.

26. The method of claim 25, wherein varying said relative position further comprises varying a distance in multiple directions.

27. The method of claim 26, wherein varying said relative position further comprises varying a speed with which said substrate passes said deposition device.

28. The method of claim 27, wherein said deposition characteristic profile comprises at least composition gradient profile and at least one morphological gradient profile.

29. The method of claim 28, wherein morphological profile comprises alternating dense film layers and porous film layers having nano-chambers.

30. The method of claim 29, wherein said deposition devices comprise sputter guns.

31. The method of claim 16, further comprising varying the distance between said deposition devices.

32. The method of claim 16, wherein forming said film comprises introducing the use of second and third deposition devices.

33. The method of claim 32, wherein forming said film comprises varying a speed with which said substrate passes said deposition devices.

34. The method of claim 33, wherein forming said film comprises varying a substrate advancement path of said substrate with respect to said deposition devices.

35. The method of claim 1, wherein said electrode comprises an anode.

36. The method of claim 35, wherein said anode is formed from a group consisting of nickel, platinum, Ni—YSZ, Cu—YSZ, Ni—SDC, Ni-GDC, Cu—SDC, Cu-GDC.

37. The method of claim 1, wherein said electrode comprises a cathode.

38. The method of claim 37, wherein said cathode is formed from a group consisting of silver, platinum, samarium strontium cobalt oxide (SSCO, SmₓSr_{y}CoO_{3-δ}), barium lanthanum cobalt oxide (BLCO, BaₓLa_{y}CoO_{3-δ}), gadolinium strontium cobalt oxide (GSCO, GdₓSr_{y}CoO_{3-δ}), lanthanum strontium manganite (LaₓSr_{y}MnO_{3-δ}) and lanthanum strontium cobalt ferrite (La_{w}SrₓCo_{y}Fe_{z}O_{3-δ}) and mixtures thereof.

39. A thin-film fuel cell electrode formed by:
providing a substrate and at least one deposition device;
developing a deposition characteristic profile based on pre-determined desired electrode properties; and
forming a compositionally-graded film in accordance with said deposition characteristic profile by sputtering material from said deposition device while varying a relative position of said substrate in relation to said deposition device with respect to at least a first axis.

40. The electrode of claim 39, further comprising providing a second deposition device and sputtering a second material from said second device onto said substrate while varying the relative position of said substrate in relation to said second deposition device with respect to at least a first axis.

41. The electrode of claim 39, wherein forming said film further comprises varying a power supplied to said deposition device.

42. The method of claim 39, wherein forming said film further comprises varying a bias of said substrate to a deposited material.

43. The method of claim 39, wherein forming said film further comprises varying an applied magnetic field.

44. The method of claim 39, wherein varying said relative position comprises advancing said substrate along a substrate advancement path.

45. The method of claim 39, wherein varying said relative position comprises varying a speed with which said substrate passes said deposition device.

46. The method of claim 40, wherein varying said relative position comprises varying a distance between said deposition devices.

47. The method of claim 46, wherein varying said relative position further comprises varying a speed with which said substrate passes said deposition device.

48. The method of claim 40, wherein varying said relative position comprises traversing said substrate back and forth past said deposition device.

49. The method of claim 48, wherein varying said relative position further comprises varying a distance in multiple directions.

50. The method of claim 49, wherein varying said relative position further comprises varying a speed with which said substrate passes said deposition device.

51. The method of claim 50, wherein said deposition characteristic profile comprises at least composition gradient profile and at least one morphological gradient profile.

52. The method of claim 51, wherein morphological profile comprises alternating dense film layers and porous film layers.

53. The method of claim 52, wherein said porous film layers comprise nano-chambers.

54. The method of claim 40, further comprising varying the distance between said deposition devices.

55. The method of claim 40, wherein forming said film comprises introducing the use of second and third deposition devices.

56. The method of claim 55, wherein forming said film comprises varying a speed with which said substrate passes said deposition devices.

57. The method of claim 56, wherein forming said film comprises varying a substrate advancement path of said substrate with respect to said deposition devices.

58. The method of claim 39, wherein said electrode comprises an anode.

59. The method of claim 58, wherein said anode is formed from a group consisting of nickel, platinum, Ni—YSZ, Cu—YSZ, Ni—SDC, Ni-GDC, Cu—SDC, Cu-GDC.

60. The method of claim 1, wherein said electrode comprises a cathode.

61. The method of claim 60, wherein said cathode is formed from a group consisting of silver, platinum, samarium strontium cobalt oxide (SSCO, SmₓSr_{y}CoO_{3-δ}), barium lanthanum cobalt oxide (BLCO, BaₓLa_{y}CoO_{3-δ}), gadolinium strontium cobalt oxide (GSCO, GdₓSr_{y}CoO_{3-δ}), lanthanum strontium manganite (LaₓSr_{y}MnO_{3-δ}) and lanthanum strontium cobalt ferrite (La_{w}SrₓCo_{y}Fe_{z}O_{3-δ}) and mixtures thereof.

62. A system for forming thin-films, comprising:
means for variably advancing a substrate;
at least one means for variably depositing material on said substrate; and
means for forming at least one layer having nano-chambers.

63. The system of claim 62, further comprising means for forming a compositional gradient on said substrate.

64. The system of claim 63, further comprising means for forming a morphological gradient on said substrate.

65. The system of claim 64, further comprising means for forming nano-pores in said morphological gradient.

66. A fuel cell, comprising:
an electrolyte located between thin film electrodes having at least one porous layer and the porous layers are of a thickness of between 10-500 nanometers.

67. The fuel cell of claim 66, wherein said porous layers are between 30-80 nanometers in thickness.
